(19) United States
(12) Patent Application Publication
(10) Pub. No.: US 2007/0022349 A1
(43) Pub. Date: Jan. 25, 2007

(54) Test apparatus with tester channel availability identification

(75) Inventors: Domenico Bertocelli, Pessano con Bomago (MI) (IT); Fabrizio Arca, Terni (TR) (IT)

Correspondence Address: Paul D. Greeley, Esq.;Ohlandt, Greeley, Ruggiero & Perle, L.L.P., 10th Floor, One Landmark Square, Stamford, CT, 06901-2682, US

(73) Assignee: Agilent Technologies, Inc.

(21) Appl. No.: 11/176,928

(22) Filed: Jul. 7, 2005

(51) Int. Cl. G01R 31/28; G06F 11/00

(52) U.S. Cl. 714/741

(57) ABSTRACT

Automated semiconductor device tester apparatus includes a plurality of tester channels for devices under test. The apparatus includes an automated switching module, for switching an unused operative tester channel in the place of any tester channel found to be malfunctioning. The apparatus provides continued test operation irrespective of tester channel malfunctioning.

### BACKGROUND ART

The invention relates to testing a device under test.

Integrated Circuits (IC) need to be tested to assure proper operation. During testing, an IC, as a device under test (DUT), is exposed to stimulus data signals of an Automatic Test Equipment (ATE). The IC transmits corresponding response data back to the ATE. The ATE measures, processes and usually compares this response data with expected responses. The ATE usually performs these tasks according to a device-specific test program. ATE's with decentralized resources based on a per-pin architecture are known, wherein during test, each pin of a plurality of pins of the DUT is connected to one ATE pin electronic. The per-pin architecture generally enables high performance and scalability.

Examples of ATE's with per-pin architecture are the Agilent 83000 and 93000 families of Semiconductor Test Systems by Agilent Technologies. Details of those families are disclosed e.g. in EP-A-0 859 318, EP-A-0 864 977, EP-A-0 886 214, EP-A-0 882 991, U.S. Pat. No. 5,499,248 and U.S. Pat. No. 5,453,995.

Essentially, testing apparatus of the kind considered in the foregoing is made up by a series of tester channels, acting each as an independent tester machine. For instance, in an Agilent 93000 (93K) testing apparatus, the tester channels are grouped in boards, each board containing 16 channels, and in the standard 93K configuration, the Agilent tester machine in question includes up to 1024 tester channels.

When even a single tester channel is affected by malfunctioning, then a “down” of the whole tester machine occurs. Any channel malfunctioning thus leads to downtime in the tester machine as a whole, and the main reason for tester downtime is thus malfunctioning of any of these channels. Machine downtime strongly affects production throughput, and the costs associated with testing. In any case, such “down” events negatively impact on machine reliability.

When channel malfunctioning occurs, the following steps might be taken:

a) testing is stopped; the tester is DOWN;

b) diagnostic software is run to locate the malfunctioning channel;

c) the channel board containing the channel that failed must be replaced by a new board; this is handled as a spare part, which requires placing an order to a source of spare parts and typically involves a time of delivery of 24-48 hours;

d) once received, the new board is installed by a trained technician;

e) diagnostic software is again run (this requires 1 hour on the average); and

f) self-calibration is typically performed (3 hours average)

Only at this point of time, the ATE tester machine will be “up” and running again.

Machine downtime, i.e. the time the machine is not working, will add up to the sum of the times required for all of the operations a) to f) described in the foregoing.

### DISCLOSURE

An object of the invention is to provide an improved testing a device under test. These and other objects are achieved by means of the invention as defined in the claims that follow.

A basic idea underlying a preferred embodiment of the invention is to automatically “swap” for the malfunctioning tester channel another channel that is available and is a “good” one, i.e. properly operating.

Preferably, this swapping or switching action is performed through a software (S/W) switch and a hardware (H/W) switch. A number of alternatives are available for implementing such a H/W switch function. These alternatives may involve switching inside the ATE (e.g. switches between neighboring channels), the DUT board design (i.e. relays on the DUT board), or using reconfigurable scan chains.

So, while waiting for the new tester board that should replace the board containing the failing channel, the tester machine itself will not stop testing. This reduces the downtime of semiconductor testing apparatus such as Automated Test Equipment or ATE.

Preferably, the tester software operates on the basis of certain files stored in the tester program directory, i.e.:
a) model file: this file contains information regarding all the channels of the tester available in the tester itself;
b) pinconfig file: this is a pin configuration file contains information regarding all the channels of the tester used by a test program;
c) diagnostic log file: this file contains information regarding the failing channels on the tester.

When malfunctioning is detected by diagnostic software in a tester channel, a script such as a PERL (Practical Extraction and Reporting Language) script will automatically replace the malfunctioning tester channel with another channel available in the tester.

In an embodiment, a semiconductor testing apparatus is provided in the form of a self-detecting, self-repairing, and virtually downtime-exempt machine.

### BRIEF DESCRIPTION OF THE DRAWINGS

Embodiments of the present invention will now be described, by way of non-limiting examples, with reference to the attached figures of drawing, in which:

FIG. 1 is a schematic, partially exploded perspective view of test apparatus adapted to incorporate the arrangement described therein,

FIG. 2 is a functional block diagram of apparatus as shown in FIG. 1,

FIG. 3 is a flow chart representative of possible operation of semiconductor testing apparatus as described herein.

In the following description, numerous specific details are given to provide a thorough understanding of embodiments of the invention. One skilled in the relevant art will recognize, however, that the invention can be practiced without one or more the specific details or with other methods, components, materials and so on.

In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessary or referring to the same embodiment. Furthermore, the particular features, structures, or characteristic may be combined in any suitable manner in one or more embodiments.

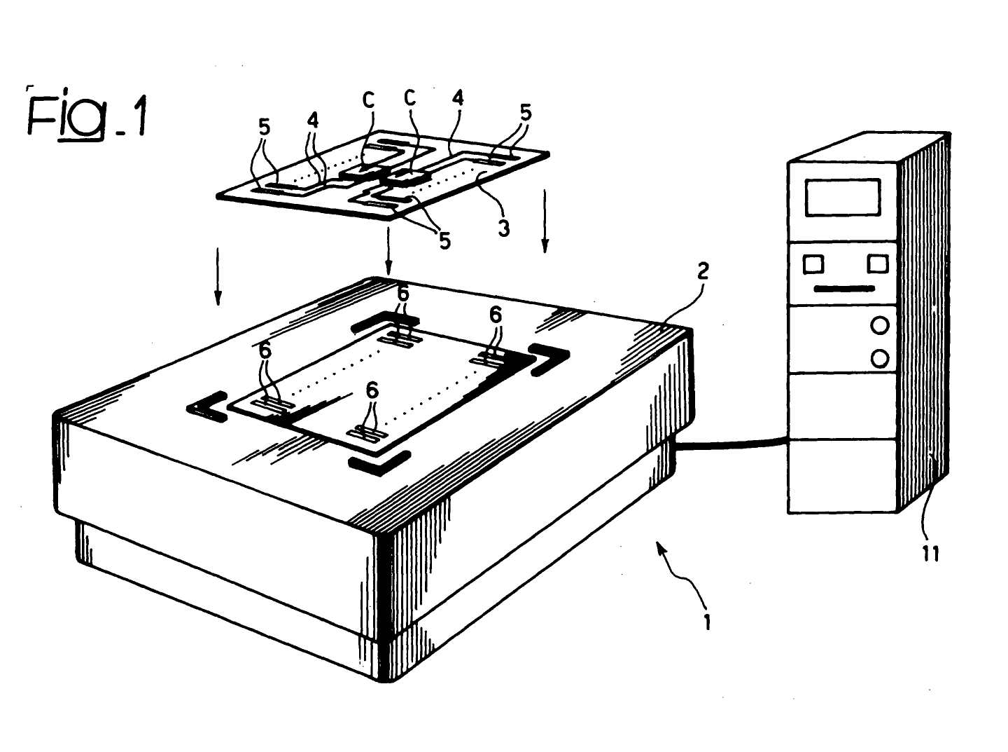

FIG. 1 is a schematic prospective view of apparatus 1 for use in testing Integrated Circuits (IC's) in order to assure proper operation thereof. During testing, an IC, as a device under test (DUT), is exposed to stimulus data signals generated by the Automatic Test Equipment (ATE) 1. The IC transmits corresponding response data back to the ATE. The ATE measures, processes and usually compares this response data with expected responses. The ATE usually performs these tasks according to a device-specific test program.

In a typical exemplary arrangement the equipment (ATE) 1 includes a bench structure 2 onto which the Devices Under Test (DUTs) are arranged.

Specifically, in the view of FIG. 1, one or more DUTs in the form of semiconductor integrated circuits C are shown mounted a DUT board 3. The DUT board 3 is essentially in the form of a large (e.g. 60×40 cm) printed circuit (PC) board including a central portion onto which the devices C are arranged. The DUT board 3 includes a large plurality of lines 4 each of which connects one pin or contact (“ball”) of a device under test—which may be a packaged device as well as a “naked” chip—to at least one connecting pad arranged at the board periphery. These connecting pads are typically arranged in arrays 5 at the lower side (underside) of the board 3.

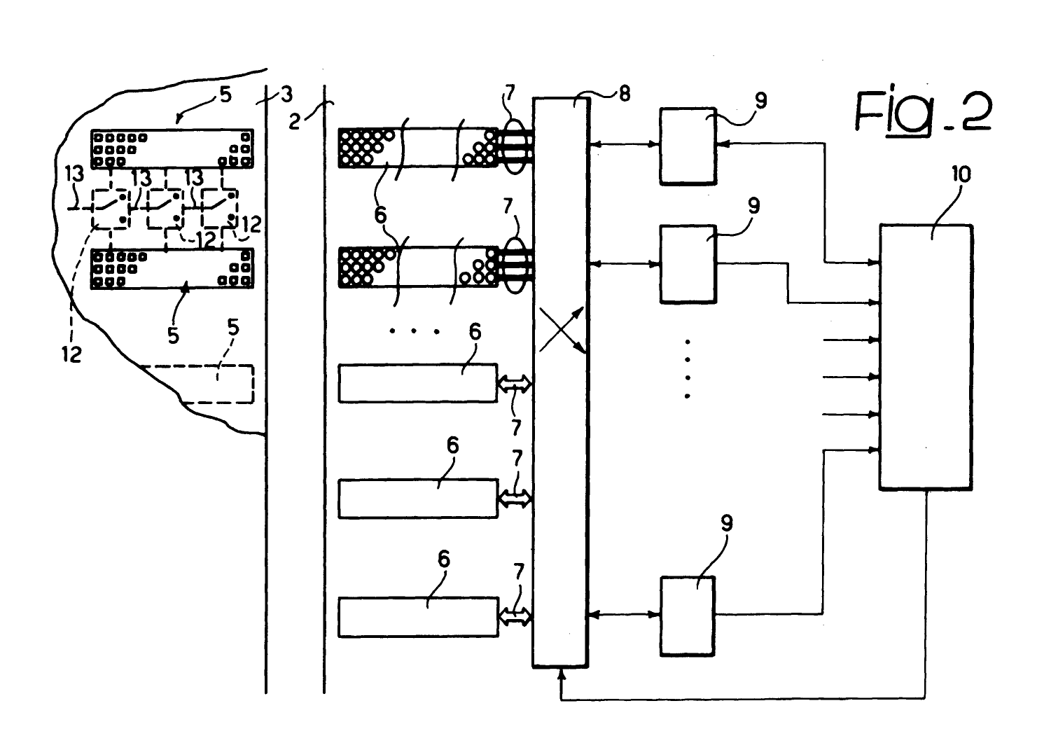

As better shown in FIG. 2, each array 5 is usually comprised of a matrix of contact pads. Each such array 5 in the DUT board is mirrored by a corresponding array 6 of contact pins at the upper plane of the bench portion 2 of the ATE 1. These contact pins (currently referred to as “pogo pins”) establish electrical connection to the contact pads 5 and thus to the pins or “balls” of the devices C under test.

During the test process, the connections established via lines 4, the contact pads in the arrays 5 and the “pogo pins” 6 are used to apply to the circuits C signals in the form of “stimuli” and to collect corresponding “reactions” or “responses” from the circuits. The absence of these reactions/responses or these reactions/responses being different from those expected is generally construed as evidence of fault or malfunctioning of any circuit C tested.

All of the foregoing corresponds to principles of operation that are well known in the art, thus making it unnecessary to provide a more detailed description herein.

As better detailed in FIG. 2, each array of pogo pins 6 represents the “distal” end of a corresponding tester channel 7. Each such channel is connected, via a switch matrix 8 to be better detailed in the following, to a tester board 9. Typically ATEs of the Agilent 93k series include 1024 channels grouped in 64 boards, each board thus having associated therewith 16 channels. The tester boards 9 are typically arranged in the bench structure 2 of the ATE and come down to a main tester unit 10 housed in a central shelf 11 where user interfaces (GUIs and the like) are arranged.

Malfunctioning of any of the tester channels 7 is a highly undesirable event, and the unit 10 includes software automation to detect malfunctioning channels.

In the presently preferred embodiment of the arrangement described herein, defective channel detection is performed by means that are known per se, e.g. via the diagnostic routines already available in the software module designated HPSmartest™ equipping the Agilent 93K test machinery.

The tester software operates on the basis of certain files stored in the associated memory of the unit 10. Specifically, these files, as included in the tester program directory are:
a) a model file: this file contains information regarding all the channels of the tester available in the tester itself;
b) a pinconfig file: this is a pin configuration file contains information regarding all the channels of the tester used by a test program; and
c) a diagnostic log file: this file contains information regarding the failing channels on the tester.

A basic concept underlying the arrangement described herein lies in that, if one of the channels 7 is found to be defective, another good but unused channel 7 replaces the defective channel in the pinconfig file.

Specifically, a script such a PERL script replaces the defective channel with the good one in the pinconfig file. The good but unused channel then physically replaces the defective channel on the DUT board.

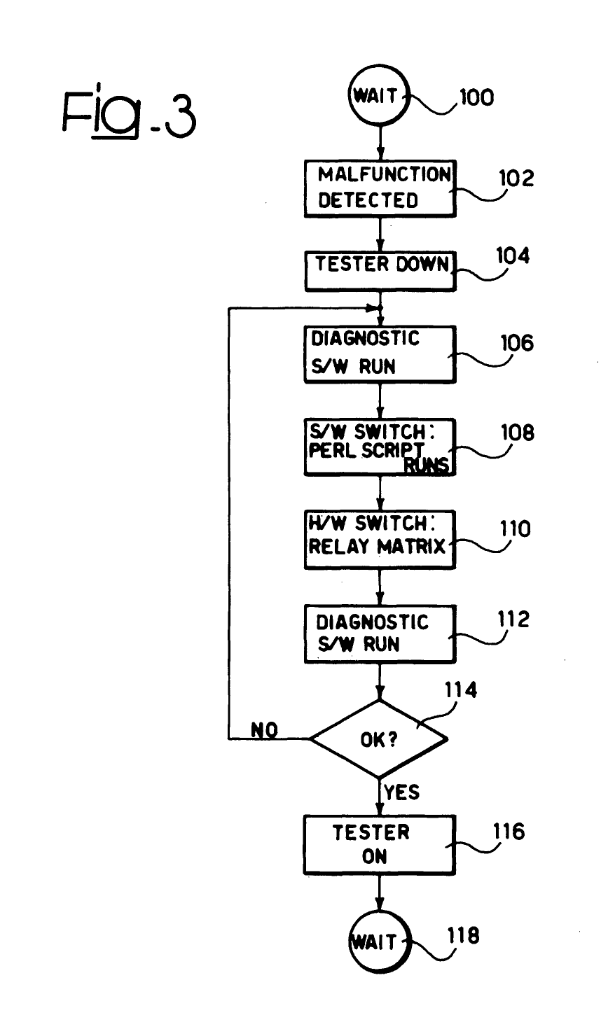

An exemplary mode of operation of the arrangement just considered will now be described with reference to the flow-chart of FIG. 3.

Starting from a WAIT state 100, which is exemplary of regular operation of the tester equipment, a step 102 is representative of a tester channel malfunctioning event being detected (as indicated, this function is performed by known means, not illustrated in detail herein).

As a consequence, in a step 104 testing operation is discontinued. The tester equipment 1 is DOWN.

Then, in a step 106 diagnostic software is run (this is already available as a part of the Agilent 93K tester software), and the malfunctioning channel 7 is identified.

In a step 108 a script such as e.g. a PERL (Practical Extraction and Reporting Language) script scans the log file described in the foregoing to find out the malfunctioning channel. Specifically, the script scans two of the files included in the tester software directories stored in the unit 10, namely:
i) a model file containing information regarding all the channels of the tester available in the tester itself (i.e. the “tester_channels”) and
ii) a pin configuration file (“pinconfig file”) containing information regarding all the channels of the tester used by test program (i.e. the “used_channels”).

The script scans and compares the model and pinconfig file finding out the tester channels that are available and not used. The script achieves this result by comparing the groups “tester_channels” vs. “used_channels”.

The PERL script thus finds out a group of “spare_channels”. Any channel belonging to the group “spare_channels” can be used to replace a malfunctioning channel belonging to the group of “used_channels”.

The script modifies the pinconfig file by replacing the channel 7 found to be malfunctioning with an operative channel taken from the group “spare_channels”. In that way, a switching action is performed by replacing a malfunctioning channel with a channel that is both available and a “good” one.

Then, in a step 110, physical switching is performed to substitute the tester channel 7 found to be malfunctioning by means of another tester channel that is available and is a “good” one, i.e. a tester channel adapted to ensure proper tester operation.

A number of options are available for performing the “physical” switching action considered here.

A first, presently preferred option relies on the switch matrix 8 shown in FIG. 2. In a preferred embodiment, the matrix in question is a solid state relay switch matrix. Such switch matrixes are commonly used in a wide variety of electronic devices such as e.g. private and public exchanges in telephone networks. Use of those matrixes has also been proposed in ATE's, for instance for testing so-called “stacks” including a plurality of superposed devices having respective layers of pins or “balls” that require different connection arrangements for testing the various devices in the stacks.

In brief, once a given channel 7 is found to be malfunctioning, the matrix 8 (which operates under the control of the unit 10) ensures that the array of “pogo pins” 6 and the tester board 9 connected via the malfunctioning channel are re-connected via a “good” channel, thus ensuring the possibility of continuing the test process.

As an alternative, a corresponding mode of operation can be ensured by resorting to a dedicated board design for all channels through relays 12 (schematically shown in phantom line in FIG. 2) included in the DUT board 3. In that way, all channels 7 may be connected to respective relays 12 that will be responsible to replace any failing channel with a channel that is operative and not currently used. While not unlikely to increase to some extent surface occupancy of the DUT board 3, this alternative arrangement has an inherent advantage in that the switch relays 12 can be controlled by the unit 10 via so-called “utility” lines 13 that are already currently available on the DUT board 3.

Still a further alternative (not explicitly shown in the drawings) provides for “virtual” switching along the lines described in the foregoing being achieved via corresponding changes in the so-called “scan-chains” of the devices C.

Whatever the specific option adopted for channel H/W switching, once such channel switching has been achieved, in a step 112, a diagnostic software is run. If such diagnostic routine provides a positive result (step 114), the tester is set ON so that testing is restarted (step 116), while the system returns to the WAIT condition (step 118). In the case of a negative result in step 114, operation of the system returns to the step 106.

The steps described in the foregoing are preferably integrated to a single step software process in that the diagnostic routine itself, once having detected a malfunctioning channel, will call the PERL script. This means that the steps described above will in fact be integrated into the diagnostic routine, running in automatic mode after any tester stop due to a malfunctioning being detected.

It will be appreciated that the type of operation described embodies the concept of a truly self detecting/repairing tester machine. Additionally, those of skill in the art will appreciate that the arrangement just described lends itself to introducing redundant spare channels in a tester machine for use if the testing apparatus is already using all the tester channels available.

Pseudo-code representative of a PERL script adapted for use within the framework of the arrangement described herein will now be described in detail.

The main program of the script executes the following functions:

| | |
|---|---|
| &scan_diag( ); | # from diagnostic file finds out |
| | tester failing channels |
| &scan_model( ); | # from model file finds out |
| | tester available channels |
| &scan_config( ); | # from pin config file finds out |
| | tester used channels |
| &scan_free( ); | # finds out tester free |
| | channels |
| &backup_config( ); | # creates a backup of pin config |
| &modify_config( ); | # replaces in pin config |
| | failing_channels with |
| | available_channels |

By scanning this part of the model file, &scan_model( ) finds out the available channels in the tester i.e. the “tester_channels”):

IOCHANNEL
10101-10216: sram = 2M, sdram = 112M
10301-11416: sram = 2M, sdram = 14M
11501-11616: sram = 2M, sdram = 112M
11701-13216: sram = 2M, sdram = 14M
20101-20516: sram = 2M, sdram = 14M

By scanning this part of the pinconfig file, &scan_config( ) finds out the channels of the tester used by the test program (i.e. the “used_channels”):

hp93000,config,0.1
DFPN 10702, “3”, (cari_pwm)
DFPN 10703, “4”, (paper_pwm)
DFPN 10704, “5”, (serv_pwm_b)
DFPN 10705, “8”, (rom_adr18)
DFPN 10706, “9”, (serv_pwm_a)
DFPN 10707, “10”, (aload)
DFPN 10708, “11”, (obs_bus13)

Then, &scan_free( ) finds out the tester channels that are free and &modify_config( ) replaces in pin config the failing_channel with available_channels.

At this point a warning is issued on the display of the Tester Machine:

print “\n\n\n\n”;
print “ !!!!!ATTENTION!!!!! THIS
CHANNEL IS FAILING: $failing_channels[$t]\n”;
print “ REPLACE IT ON THE BOARD WITH
THIS UNUSED CHANNEL: $free_channels[$t]\n”;
print “\n\n”;
print “ PIN CONFIGURATION HAS BEEN
ALREADY UPDATED BY THIS SCRIPT ”;

The diagnostic software (step 106) can be run on the tester manually, by a technician, after an error occurred in the tester. However, the arrangement described herein preferably contemplates the possibility for this software to be run periodically, when the machine is STOPPED but not DOWN, i.e. behaving essentially like the SCANDISK program running on a PC. If a failing channel is detected, then the channel switch/swap procedure described is started automatically.

It will be appreciated that the arrangement described herein provide an appreciable increase in the uptime of the testing equipment described by improving performance thereof in terms of mean time between failures (MTBF). This is particularly important, especially for high pin count digital systems expected to be used in cost sensitive multi-site environments.

The arrangement described herein involves the use of relays (relay unit 20) on the DUT board. For certain applications such an arrangement may turn out not to be particularly practical because of space and reliability concerns. The switching process described in the foregoing can however be performed elsewhere within the automated test equipment (ATE), for instance by arranging switches between neighboring channels or within the device under test (DUT), by using e.g. reconfigurable scan chains.

The above description of illustrated embodiments of the invention, including what is described in the abstract, is not intended to be exhaustive or to limit the invention to the precise form disclosed. While specific embodiments of, and examples for, the invention are described herein for illustrative purposes, various equivalent modifications are possible within the scope of the invention and can be made without deviating from the spirit and the scope of the invention.

These and other modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

1. An automated tester apparatus comprising:
a first tester channel and a second tester channel;
a model file that indicates whether said first and second tester channels are available;
a pin configuration file that indicates whether said first and second tester channels are in use; and
a script that scans said model file and said pin configuration file to identify said second tester channel as being available as a substitute for said first tester channel when said first tester channel malfunctions.

2. The apparatus of claim 1, further comprising a malfunction detection module that generates a log file that identifies said first tester channel when said first tester channel malfunctions.

3. The apparatus of claim 2, wherein said script scans said log file to identify said first tester channel when said first tester channel malfunctions.

4. The apparatus of claim 1, wherein said script is a PERL (Practical Extraction and Reporting Language) script.

5. The apparatus of claim 1, further comprising a switch that switches said second tester channel in place of said first tester channel.

6. The apparatus of claim 1, further comprising:
a third tester channel; and
a switch matrix controllable to switch either of said second or third tester channels in place of said first tester channel.

7. The apparatus of claim 5, wherein said switch includes a relay to activate said second tester channel in place of said first tester channel.

8. An automated tester apparatus comprising:
a first tester channel and a second tester channel;
a detector module that detects a malfunction of said first tester channel; and
a switch for switching said second tester channel in place of said first channel when said detector module detects said malfunction of said first tester channel.

9. The apparatus of claim 8, wherein said detector module generates a log file that identifies said first tester channel when said first tester channel malfunctions.

10. The apparatus of claim 8, further comprising:
a third tester channel; and
a switch matrix controllable to switch either of said second or third tester channels in place of said first tester channel,
wherein said switch is a component of said switch matrix.

11. The apparatus of claim 8, wherein said switch includes a relay to activate said second tester channel in place of said first tester channel.

12. The apparatus of claim 8, further comprising:
a module for stopping operation of said first and second tester channels,
wherein said detector module is activated in concurrence with said stopping.

13- 15. (canceled)

16. The apparatus of claim 8, wherein said apparatus provides continued test operation irrespective of tester channel malfunctioning.

17. A method of operating an automated tester apparatus that includes a first tester channel and a second tester channel, the method comprising:
providing a model file that indicates whether said first and second tester channels are available;
providing a pin configuration file that indicates whether said first and second tester channels are in use;
scanning said model file and said pin configuration file to identify said second tester channel as being available as a substitute for said first tester channel when said first tester channel malfunctions; and
substituting said second tester channel for said first tester channel when said first tester channel malfunctions.

18- 24. (canceled)

25. The method of claim 17, further comprising:
detecting that said first tester channel malfunctions,
wherein said substituting comprises switching said second tester channel in place of said first tester channel.

26-27. (canceled)

28. The method of claim 25, further comprising:
stopping operation of said first and second tester channels,
wherein said detecting is performed in concurrence with said stopping.

29. (canceled)

30. The method of claim 17, wherein said substituting is performed while said apparatus provides continued test operation irrespective of tester channel malfunctioning.
